(19) United States
(12) Patent Application Publication
(10) Pub. No.: US 2025/0379582 A1
(43) Pub. Date: Dec. 11, 2025

(54) LOGIC GATE

(71) Applicant: UNIVERSITY OF LANCASTER, Lancaster Lancashire (GB)

(72) Inventors: Manus HAYNE, Lancaster, Lancashire (GB); Jonathan Joseph HALL, Northumberland (GB)

(73) Assignee: UNIVERSITY OF LANCASTER, Lancaster Lancashire (GB)

(21) Appl. No.: 18/877,070

(22) PCT Filed: Jun. 8, 2023
(86) PCT No.: PCT/GB2023/051493

§ 371 Date: Dec. 19, 2024

(30) Foreign Application Priority Data
Jun. 27, 2022 (GB) 2209395.9

(51) Int. Cl. H03K 19/08; H10D 62/81; H10D 84/85; H10D 84/90

(52) U.S. Cl. CPC H03K 19/08; H10D 62/81; H10D 84/85; H10D 84/953

(57) ABSTRACT

There is provided a logic gate comprising a semiconductor device. The semiconductor device includes a charge reservoir layer disposed between a first charge accepting layer and a second charge accepting layer. The first charge accepting layer defines a first current flow path that is connected to a common output contact at one end and a drive contact at the other end. The second charge accepting layer defines a current flow path that is connected to the common output contact at one end and a ground contact at the other end. The charge reservoir layer comprises a potential well having a lowest energy state for mobile charge carriers that is at a lower energy than the lowest energy state for mobile charge carriers of both the first and second charge accepting layers. The logic gate further comprises a control gate and a ground electrode that are separated from the charge accepting layers by non-conducting layers. The control gate and the ground electrode are configured to apply an input voltage across the semiconductor device, such that mobile charge carriers confined within the charge reservoir layer are transferred to the first charge accepting layer at a first applied input voltage and transferred to the second charge accepting layer at a second applied input voltage.

The present invention relates to a logic gate, and more particularly to a digital logic gate for use in digital circuits.

Logic gates are devices that act as building blocks for digital circuits, and perform basic logical functions that are fundamental to those digital circuits. Digital computing is based on CMOS (complementary metal oxide semiconductor) logic gates, which are made up of pairs of devices (transistors, or switches) that show complementary behaviour in use. That is, in use, when one of the pair is on, the other of the pair is off, and vice versa. In all known configurations of CMOS logic gates, this is achieved by one of the pair being an n-type semiconductor (nMOS), and the other of the pair being a p-type semiconductor (pMOS).

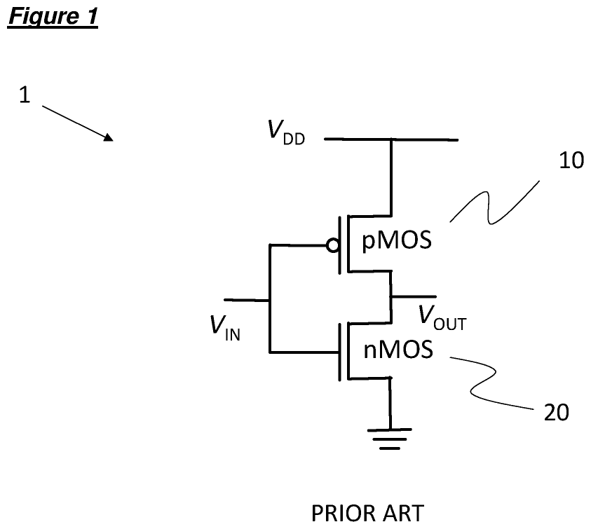

The principles of a conventional CMOS gate are discussed with reference to FIG. 1, which illustrates the simplest of conventional logic gates, the NOT gate. The NOT gate 1 of FIG. 1 consists of a p-MOS 10 and an n-MOS 20 connected in series. A high drive voltage V_{DD} (eg of +2.5V) is applied to the gate 1 throughout operation, and an input voltage V_{IN} can be applied to the gate 1 to control the behaviour of the pMOS 10 and the nMOS 20.

For example, where the input voltage V_{IN} is high, a high resistance is created across the pMOS 10, whereas a low resistance is created across the nMOS 20. This prevents current from flowing across the pMOS 10, meaning that all of the drive voltage V_{DD} is dropped across the pMOS 10, and the output voltage V_{OUT} is 0.

In contrast, where the input voltage V_{IN} is low, a low resistance is created across the pMOS 10, whereas a high resistance is created across the nMOS 20. This allows current to flow across the pMOS 10, meaning that all of the drive voltage V_{DD} is recognised in the output voltage V_{OUT}.

The resultant outcome is that when the input voltage V_{IN} is high, the output voltage V_{OUT} is low, and when the input voltage V_{IN} is low, the output voltage V_{OUT} is high, and this arrangement relies on pairs of devices with the singular requirement that, with the same input, when one is in a high resistance state, the other is in a low resistance state, and vice versa. This same principle is used to build up other logic gates such as AND gates, NAND gates, OR gates, and NOR gates.

Since one of the pMOS and the nMOS is always in an “off” state, CMOS logic gates only draw significant power momentarily during switching between “on” and “off” states. Consequently, CMOS devices are generally preferable to other forms of logic because they do not produce as much waste heat.

However, the inventors have recognised that further benefits can be recognised over and above those achieved by CMOS logic gates. There has now been devised an improved logic device, which overcomes or substantially mitigates disadvantages associated with the prior art.

According to a first aspect of the invention, there is provided a logic gate comprising a semiconductor device, the semiconductor device including a charge reservoir layer disposed between a first charge accepting layer and a second charge accepting layer, the first charge accepting layer defining a first current flow path that is connected to a common output contact at one end and a drive contact at the other end, and the second charge accepting layer defining a current flow path that is connected to the common output contact at one end and a ground contact at the other end, the charge reservoir layer comprising a potential well having a lowest energy state for mobile charge carriers that is at a lower energy than the lowest energy state for mobile charge carriers of both the first and second charge accepting layers, the logic gate further comprising a control gate and a ground electrode that are separated from the charge accepting layers by non-conducting layers, the control gate and the ground electrode configured to apply an input voltage across the semiconductor device, such that mobile charge carriers confined within the charge reservoir layer are transferred to the first charge accepting layer at a first applied input voltage and transferred to the second charge accepting layer at a second applied input voltage.

At the first applied input voltage, the lowest energy state for mobile charge carriers of the first charge accepting layer may be at a lower energy than the lowest energy state for mobile charge carriers of both the charge reservoir layer and the second charge accepting layer.

At the second applied input voltage, the lowest energy state for mobile charge carriers of the second charge accepting layer may be at a lower energy than the lowest energy state for mobile charge carriers of both the charge reservoir layer and the first charge accepting layer.

The present invention may be advantageous in that the logic gate according to the invention reduces the number of devices required to implement a digital logic gate. For example, as described above, relative to the simplest of conventional logic gates, the NOT gate, the logic gate according to the invention requires half the number of devices required by a conventional CMOS gate. Where the conventional CMOS gate requires one nMOS device and one pMOS device, the logic gate according to the invention provides a first charge accepting layer that effectively acts as the pMOS of the conventional CMOS gate, and a second charge accepting layer that effectively acts as the nMOS of the conventional CMOS NOT gate. This makes the logic gate of the invention, and any circuit comprising the logic gate of the invention, much more compact.

The invention may be further advantageous in that the logic gate of the invention operates symmetrically. That is, the application of the first applied input voltage has a first effect on the transfer of mobile charge carriers, and the application of the second applied input voltage has an equal and opposite effect on the transfer of mobile charge carriers. In contrast, in a conventional CMOS gate, it is difficult to implement an nMOS and a pMOS with equivalent, but opposite, characteristics. It is believed that the fundamental reason for this is that electrons are more mobile than holes, because the movement of holes actually requires the movement of a lack of electrons. Thus, the pMOS performance in a conventional CMOS is inferior to that of the nMOS, and the logic gate as a whole is limited to the performance of the pMOS. In contrast, the logic gate of the invention only requires one type of charge carrier. Where those charge carriers are electrons, this problem is mitigated.

It is also believed that the invention is advantageous in reducing power dissipation. The main source of power dissipation in conventional CMOS logic gates arises due to both the nMOS and the pMOS being in an “on” state momentarily when switching the input voltage, ie between a first applied input voltage and a second applied input voltage. However, since the input voltage is switched so often, due to the high speed of modern digital logic circuits, over time a large amount of power is dissipated. In contrast, simulations of the logic gate according to the invention suggest that the power dissipation is reduced, because there is no applied input voltage at which both charge accepting layers are simultaneously conductive, ie in an “on” state. In particular, simulations of the logic gate according to the invention suggest that there is no applied input voltage for which there are sufficient mobile charge carriers in both accepting layers to enable them to be simultaneously sufficiently conductive, ie in an “on” state.

The logic gate may comprise a substrate layer. The semiconductor device may be grown on the substrate layer.

The first charge accepting layer, the second charge accepting layer, and the charge reservoir layer may form an active layer. The control gate may be disposed on a first external surface of the active layer. The ground electrode may be disposed on a second external surface of the active layer. The first and second external surfaces may be different surfaces. The first and second external surfaces may be opposite surfaces of the active layer. For example, the control gate may be disposed on a top surface of the active layer and the ground electrode may be disposed on a bottom surface of the active layer.

Alternatively, the semiconductor device may comprise one or more additional layers disposed between the active layer and the control gate and/or the ground electrode.

For example, the control gate may be separated from the first charge accepting layer by a first external charge barrier disposed on an external surface of the first charge accepting layer, ie disposed on the opposite side of the first charge accepting layer to the charge reservoir layer. Additionally, the ground electrode may be separated from the second charge accepting layer by a second external charge barrier disposed on an external surface of the second charge accepting layer, ie disposed on the opposite side of the second charge accepting layer to the charge reservoir layer. The external charge barriers may therefore be referred to as non-conducting layers, or even insulating layers. Where the logic gate further comprises a substrate layer, the second external charge barrier may be disposed between the second charge accepting layer and the substrate.

In this arrangement, the control gate may be disposed on an external surface of the first external charge barrier, ie disposed on the opposite side of the first external charge barrier to the first charge accepting layer, and the ground electrode may be disposed on an external surface of the second external charge barrier, eg between the second external charge barrier and the substrate.

The input voltage may be applied across each of the charge reservoir layer, the first charge accepting layer and the second charge accepting layer.

The drive contact and the ground contact may be for applying a drive voltage across the device. The drive voltage may be applied across each of the charge reservoir layer, the first charge accepting layer and the second charge accepting layer. The drive voltage may be a constant voltage.

The common output contact may be for providing an output voltage. The output voltage may be dependent on the conductivity of the first and second charge accepting layers. Since the conductivity of the first and second charge accepting layers is dependent on the presence of mobile charge carriers in those layers, and the presence of mobile charge carriers in those layers is dependent on the input voltage, the output voltage may therefore be dependent on the input voltage. Thus, the output voltage may be controlled by controlling the input voltage.

Some or all of the control gate, the ground electrode, the common output contact, the drive contact, and the ground contact may be connectable to other parts of a device, eg another part of an integrated circuit, to ground, or to another logic gate. This connection may enable a drive voltage to be applied to the logic gate via the drive contact and/or the input voltage to be applied to the logic gate via the control gate. This may also enable an output voltage to be output from the logic gate via the common output contact. That is, any of the drive voltage, the input voltage and the output voltage may be provided by or to an external source.

Some or all of the control gate, the ground electrode, the common output contact, the drive contact, and the ground contact may be formed of a metallic material. Alternatively, some or all of the control gate, the ground electrode, the common output contact, the drive contact, and the ground contact may be formed of a semiconductor material. For example, the control gate may be formed by a conductive layer disposed between the first charge accepting layer and the first external surface of the semiconductor device. Similarly, the ground electrode may be formed by a conductive layer disposed between the second charge accepting layer and the second external surface. This arrangement may be advantageous in many implementations, as it can reduce the distance between the control gate and the ground electrode in use, thus increasing the electric field for a given input voltage, and can also provide a common ground electrode for multiple devices integrated on the same chip, to which different input voltages may be applied. Although not necessary, the common output contact and/or the drive contact and/or the ground contact may be either n-doped or p-doped.

The charge reservoir layer may be doped. The charge reservoir layer may be doped prior to the application of an input voltage. This may induce charge carriers in the charge reservoir layer. The semiconductor device may be configured such that in the absence of an input voltage, those induced charge carriers remain in the charge reservoir layer. Alternatively, the first charge accepting layer and the second charge accepting layer may also be doped, and the charge reservoir layer may be doped to a different extent, eg a greater or lesser extent. Again, this may induce charge carriers in the charge reservoir layer. The semiconductor device may be configured such that in the absence of an input voltage, those induced charge carriers remain in the charge reservoir layer.

The semiconductor device may comprise a heterostructure. The semiconductor device may have a heterojunction at the interface between the first charge accepting layer and the charge reservoir layer. The semiconductor device may have a heterojunction at the interface between the charge reservoir layer and the second charge accepting layer. The potential well of the charge reservoir layer may comprise a quantum well. The quantum well of the charge reservoir layer may be defined between the first charge accepting layer and the second charge accepting layer. The quantum well of the charge reservoir layer may be formed by the charge reservoir layer having offset conduction and/or valence bands to form heterojunctions at the interfaces between the charge reservoir layer and the first charge accepting layer, and/or between the charge reservoir layer and the second charge accepting layer. For example, the charge reservoir layer may have a conduction band minimum energy that is lower than the conduction band minimum energy of the first charge accepting layer and the conduction band minimum energy of the second semiconductor layer, thus forming a quantum well.

The offset conduction and/or valence bands of the charge reservoir layer may be achieved by selecting different semiconductors for adjacent layers, thereby defining a quantum well in the conduction and/or valence bands. That is, the offset conduction and/or valence bands of the charge reservoir layer may be achieved by forming the charge reservoir layer with a different semiconductor to the semiconductor, or semiconductors, used to form the first charge accepting layer and the second semiconductor layer. Where the first charge accepting layer and/or the second charge accepting layer comprises more than one semiconductor, the offset conduction and/or valence bands of the charge reservoir layer may be achieved by forming the charge reservoir layer with a different semiconductor to the semiconductor used in the adjacent layer of the first charge accepting layer and/or the second semiconductor layer.

The charge reservoir layer may therefore be formed by a narrower band gap semiconductor being disposed between two wider band gap semiconductors, thereby providing a heterojunction structure. That is, the charge reservoir layer may be formed by a narrower band gap semiconductor and the adjacent first and second charge accepting layers may be formed by a wider band gap semiconductor. By “band gap” it is meant the energy gap between the valence and conduction bands of the semiconductor.

The semiconductor of the charge reservoir layer and the semiconductor of the first and second charge accepting layers may be formed of any semiconductors that provide the required barrier potentials, eg the required heterojunctions. For example, the semiconductors may comprise group IV semiconductors such as Si, or alloys of group IV semiconductors such as SiGe, or the semiconductors may comprise II-VI semiconductors and their alloys, or the semiconductors may comprise of other materials, such as those known as 2D materials. In presently preferred embodiments, the semiconductors comprise III-V semiconductors, or alloys of III-V semiconductors. For example, the charge reservoir layer may be formed of gallium arsenide (GaAs), and the first and/or second charge accepting layer may be formed of aluminium gallium arsenide (AlGaAs). Alternatively, the charge reservoir layer may be formed of indium arsenide (InAs), and the first and/or second charge accepting layer may be formed of indium gallium arsenide (InGaAs).

Further alternatively, the charge reservoir layer and the first and/or second charge accepting layer may be formed of the same semiconductor material, and the required barrier potentials may be provided by a variation in any of the constituent elements of the semiconductor material. For example, the charge reservoir layer and the first and second charge accepting layers may all be formed of AlGaAs, and the fractional Al content in the charge reservoir layer may be lower than in the first and second charge accepting layers. Alternatively, the charge reservoir layer and the first and second charge accepting layers may all be formed of InGaAs, and the fractional Ga content in the charge reservoir layer may be lower than in the first and second charge accepting layers.

The quantum well of the charge reservoir layer may have discrete internal energy levels for accommodating mobile charge carriers in the charge reservoir layer. The discrete energy levels of the charge reservoir layer may correspond to one or more confined internal states into which (and out of which) mobile charge carriers can pass.

The lowest energy state at which a mobile charge carrier may reside in a conduction band of the first charge accepting layer and/or the second charge accepting layer may have a higher energy than the lowest discrete energy level of the charge reservoir layer. The first charge accepting layer and/or the second charge accepting layer may therefore be unoccupied by mobile charge carriers in the absence of an input voltage, ie at a zero applied bias or a zero applied electric field. The first charge accepting layer and/or the second charge accepting layer may therefore provide a high resistance to current flow in the absence of an input voltage. The first charge accepting layer and/or the second charge accepting layer may therefore be non-conductive, ie insulating, in the absence of an input voltage.

The application of an input voltage across the semiconductor device may modify any of, or any combination of, the charge reservoir layer, the first charge accepting layer, and the second charge accepting layer. The shape and/or the magnitude of the conduction band of any of, or any combination of, the third charge reservoir layer, the first charge accepting layer, and the second charge accepting layer may be modified. Alternatively, or additionally, the Fermi level of the logic gate may be modified. For example, the conduction band of any of, or any combination of, the charge reservoir layer, the first charge accepting layer, and the second charge accepting layer, may become inclined across the applied electric field. In particular, the increase or decrease in the height of the conduction band across any of these layers may be proportional to its distance across the applied electric field.

In response to the application of the first applied input voltage, the lowest energy state of at least a portion of the charge reservoir layer may have a higher energy than the conduction band minimum energy of at least a portion of the first charge accepting layer. In response to the application of the first applied input voltage, at least a portion of the conduction band minimum energy of the first charge accepting layer may have a lower energy than the Fermi energy of the first charge accepting layer. Mobile charge carriers may therefore flow from the charge reservoir layer into the first charge accepting layer in response to the application of the first applied input voltage.

The first charge accepting layer may therefore become occupied with mobile charge carriers in response to the application of the first applied input voltage. The first charge accepting layer may therefore provide a low resistance to current flow in response to the application of the first applied input voltage. The first charge accepting layer may therefore become conductive in response to the application of the first applied input voltage.

The number of mobile charge carriers in the charge reservoir layer may therefore be reduced in response to the application of the first applied input voltage. The charge reservoir layer may therefore become unoccupied by mobile charge carriers in response to the application of the first applied input voltage.

In response to the application of the first applied input voltage, the lowest energy state of the charge reservoir layer may have a lower energy than the conduction band minimum energy of the second charge accepting layer. In response to the application of the first applied input voltage, the conduction band minimum energy of the second charge accepting layer may have a higher energy than the Fermi energy of the second charge accepting layer.

The second charge accepting layer may therefore remain absent of mobile charge carriers, ie mobile charge carriers may not flow from the charge reservoir layer into the second charge accepting layer in response to the application of the first applied input voltage. The second charge accepting layer may therefore remain unoccupied by mobile charge carriers in response to the application of the first applied input voltage. The second charge accepting layer may therefore continue to provide a high resistance to current flow in response to the application of the first applied input voltage. The second charge accepting layer may therefore remain non-conductive, ie insulating, in response to the application of the first applied input voltage.

In response to the application of the second applied input voltage, the lowest energy state of at least a portion of the charge reservoir layer may have a higher energy than the conduction band minimum energy of at least a portion of the second charge accepting layer. In response to the application of the second applied bias, at least a portion of the conduction band minimum energy of the second charge accepting layer may have a lower energy than the Fermi energy of the second charge accepting layer. Mobile charge carriers may therefore flow from the charge reservoir layer into the second charge accepting layer in response to the application of the second applied input voltage.

The second charge accepting layer may therefore become occupied by mobile charge carriers in response to the application of the second applied input voltage. The second charge accepting layer may therefore provide a low resistance to current flow in response to the application of the second applied input voltage. The second charge accepting layer may therefore become conductive in response to the application of the second applied input voltage.

The number of mobile charge carriers in the charge reservoir layer may therefore be reduced in response to the application of the second applied input voltage. The charge reservoir layer may therefore become unoccupied by mobile charge carriers in response to the application of the second applied input voltage.

In response to the application of the second applied input voltage, the lowest energy state of the charge reservoir layer may have a lower energy than the conduction band minimum energy of the first charge accepting layer. In response to the application of the second applied input voltage, the conduction band minimum energy of the first charge accepting layer may have a higher energy than the Fermi energy of the first charge accepting layer.

The first charge accepting layer may therefore remain absent of mobile charge carriers, ie mobile charge carriers may not flow from the charge reservoir layer into the first charge accepting layer, in response to the application of the second applied input voltage. The first charge accepting layer may therefore remain unoccupied by mobile charge carriers in response to the application of the second applied input voltage. The first charge accepting layer may therefore continue to provide a high resistance to current flow in response to the application of the second applied input voltage. The first charge accepting layer may therefore remain non-conductive, ie insulating, in response to the application of the second applied input voltage.

The mobile charge carriers may be electrons or holes. Where the mobile charge carriers are electrons, the first applied input voltage may be a positive applied input voltage and the second applied input voltage may be a negative applied input voltage. Alternatively, the first applied input voltage may be a positive applied input voltage, and the second applied input voltage may be a less positive applied input voltage. This may be the case, for example, where a positive input voltage is applied in an at rest state, ie to create the potential well of the charge reservoir layer. Further alternatively, the second applied input voltage may be a negative applied input voltage, and the first applied input voltage may be a less negative applied input voltage. This may be the case, for example, where a negative input voltage is applied in an at rest state, ie to create the potential well of the charge reservoir layer.

Where the mobile charge carriers are holes, the first applied input voltage may be a negative applied input voltage and the second applied input voltage may be a positive applied input voltage. Alternatively, the first applied input voltage may be a negative applied input voltage, and the second applied bias may be a less negative applied input voltage. This may be the case, for example, where a negative input voltage is applied in an at rest state, ie to create the potential well of the charge reservoir layer. Further alternatively, the second applied input voltage may be a positive applied input voltage, and the first applied input voltage may be a less positive applied input voltage. This may be the case, for example, where a positive input voltage is applied in an at rest state, ie to create the potential well of the charge reservoir layer.

The semiconductor device may also have a heterojunction at the interface between the first external charge barrier and the first charge accepting layer, and/or between the second charge accepting layer and the second external charge barrier. The external charge barriers may be formed of an insulator, or a semiconductor material that defines a suitably large electric potential barrier relative to the first and second charge accepting layers respectively. The external charge barriers may be formed of a dielectric material. The external charge barriers may be formed of a semiconductor material. The semiconductor may be an undoped semiconductor material. The external charge barriers may be formed of a III-V semiconductor material, for example aluminium arsenide (AlAs), or from a suitable oxide, such as silicon dioxide (SiO₂) or aluminium oxide (Al₂O₃).

In an alternative embodiment, the semiconductor device may further comprise a first internal charge barrier disposed between the first charge accepting layer and the charge reservoir layer, and/or a second internal charge barrier disposed between the charge reservoir layer and the second charge accepting layer. The semiconductor device may have a heterojunction at the interface between any, or any combination of: the first charge accepting layer and the first internal charge barrier, the first internal charge barrier and the charge reservoir layer, the charge reservoir layer and the second internal charge barrier, and the second internal charge barrier and the second charge accepting layer. In this arrangement, the quantum well of the charge reservoir layer may be defined between the first internal charge barrier and the second internal charge barrier.

The internal charge barriers may be charge trapping barriers, such as those known from U.S. Pat. No. 10,243,086. In particular, the internal charge barriers may be formed as an electric potential barrier that prevents the passage of mobile charge carriers between the charge reservoir layer and the first charge accepting layer and/or between the charge reservoir layer and the second charge accepting layer. The internal charge barriers may be resonant tunnelling barriers. These features may be advantageous in that even once an input voltage is no longer being applied, the effects of the applied bias remain. For example, where the first input voltage has been applied, and mobile charge carriers have moved into the first charge accepting layer, once the application of the first applied input voltage is stopped, at least some of the mobile charge carriers will remain in the first charge accepting layer, and thus the first charge accepting layer will remain conductive. Similarly, where the second input voltage has been applied, and mobile charge carriers have moved into the second charge accepting layer, once application of the second applied input voltage is stopped, at least some of the mobile charge carriers will remain in the second charge accepting layer, and thus the second charge accepting layer will remain conductive. This reduces the energy consumption of the logic gate, and allows it to operate as a combined memory and logic device.

In this arrangement, the first charge accepting layer may also comprise a potential well, eg a quantum well, ie in addition to the quantum well of the charge reservoir layer. The quantum well of the first charge accepting layer may be defined between the first external charge barrier and the first internal charge barrier. The quantum well of the first charge accepting layer may be formed by the first charge accepting layer having offset conduction and/or valence bands to form heterojunctions at the interfaces between the first charge accepting layer and the first external charge barrier, and/or between the first charge accepting layer and the first internal charge barrier. For example, the first charge accepting layer may have a lowest energy state for mobile charge carriers that is lower than the conduction band minimum energy of the first external charge barrier and the conduction band minimum energy of the first internal charge barrier, thus forming a quantum well.

In this arrangement, the second charge accepting layer may also comprise a potential well, eg a quantum well, ie in addition to the quantum well of the charge reservoir layer. The quantum well of the second charge accepting layer may be defined between the second external charge barrier and the second internal charge barrier. The quantum well of the second charge accepting layer may be formed by the second charge accepting layer having offset conduction and/or valence bands to form heterojunctions at the interfaces between the second charge accepting layer and the second external charge barrier, and/or between the second charge accepting layer and the second internal charge barrier. For example, the second charge accepting layer may have a lowest energy state for mobile charge carriers that is lower than the conduction band minimum energy of the second external charge barrier and the conduction band minimum energy of the second internal charge barrier, thus forming a quantum well.

The quantum well of the first charge accepting layer and/or the second charge accepting layer may be formed by the first charge accepting layer and/or the second charge accepting layer having offset conduction and/or valence bands to form heterojunctions at the interfaces between those charge accepting layers and their respective barrier layers. The offset conduction and/or valence bands of the first charge accepting layer and/or the second charge accepting layer may be achieved by selecting different semiconductors for adjacent layers, thereby defining a quantum well in the conduction and/or valence bands. That is, the offset conduction and/or valence bands of the first charge accepting layer and/or the second charge accepting layer may be achieved by forming the first charge accepting layer and/or the second charge accepting layer with a different semiconductor to the semiconductor, or semiconductors, used to form the adjacent charge barrier layers. Where the adjacent charge barrier layers comprise more than one semiconductor, the offset conduction and/or valence bands of the first charge accepting layer and/or the second charge accepting layer may be achieved by forming the first charge accepting layer and/or the second charge accepting layer with a different semiconductor to the semiconductor used in the adjacent layer of the adjacent barrier layer.

The first charge accepting layer and/or the second charge accepting layer may therefore be formed by a narrower band gap semiconductor being disposed between two wider band gap semiconductors, thereby providing a heterojunction structure. That is, the first charge accepting layer and/or the second charge accepting layer may be formed by a narrower band gap semiconductor and the adjacent charge barrier layers may be formed by a wider band gap semiconductor. By “band gap” it is meant the energy gap between the valence and conduction bands of the semiconductor.

The semiconductor(s) of the first charge accepting layer and/or the second semiconductor layer, and the semiconductor of the charge barrier layers, may be formed of any semiconductors that provide the required barrier potentials, eg the required heterojunctions.

The quantum well of the first charge accepting layer, and/or the quantum well of the second charge accepting layer, may have discrete internal energy levels for accommodating mobile charge carriers in those layers. The discrete energy levels of those layers may correspond to one or more confined internal states into which (and out of which) mobile charge carriers can pass.

The lowest energy state of the first charge accepting layer, and/or the lowest energy state of the second charge accepting layer, may have a higher energy than the lowest energy state of the charge reservoir layer. The first charge accepting layer and/or the second charge accepting layer may therefore be unoccupied by mobile charge carriers in the absence of an applied input voltage, ie at a zero applied bias. The first charge accepting layer and/or the second charge accepting layer may therefore provide a high resistance to current flow in the absence of an applied input voltage. The first charge accepting layer and/or the second charge accepting layer may therefore be non-conductive, ie insulating, in the absence of an applied input voltage.

The application of an input voltage across the logic gate may modify any of, or any combination of, the charge reservoir layer, the first charge accepting layer, the second charge accepting layer, the first internal charge barrier, and the second internal charge barrier. The shape and/or the magnitude of the conduction band of any of, or any combination of, the charge reservoir layer, the first charge accepting layer, the second charge accepting layer, the first internal charge barrier, and the second internal charge barrier, may be modified. Alternatively, or additionally, the Fermi level of the logic gate may be modified. For example, the conduction band of any of, or any combination of, the charge reservoir layer, the first charge accepting layer, the second charge accepting layer, the first internal charge barrier, and the second internal charge barrier, may become inclined across the applied electric field. In particular, the increase or decrease in the height of the conduction band across any of these layers may be proportional to its distance across the applied electric field.

In response to the application of the first applied input voltage, the lowest energy state of the charge reservoir layer may have a higher energy than the lowest energy state of the first charge accepting layer. In response to the application of the first applied input voltage, at least a portion of the lowest energy state of the first charge accepting layer may have a lower energy than the Fermi energy of the first charge accepting layer. Mobile charge carriers may therefore flow from the charge reservoir layer into the first charge accepting layer in response to the application of the first applied input voltage.

The first charge accepting layer may therefore become occupied in response to the application of the first applied input voltage. The first charge accepting layer may therefore provide a low resistance to current flow in response to the application of the first applied input voltage. The first charge accepting layer may therefore become conductive in response to the application of the first applied input voltage.

The number of mobile charge carriers in the charge reservoir layer may therefore be reduced in response to the application of the first applied input voltage. The charge reservoir layer may therefore become unoccupied by mobile charge carriers in response to the application of the first applied input voltage.

In response to the application of the first applied input voltage, the lowest energy state of the charge reservoir layer may have a lower energy than the lowest energy state of the second charge accepting layer. In response to the application of the first applied input voltage, the lowest energy state of the second charge accepting layer may have a higher energy than the Fermi energy of the second charge accepting layer.

The second charge accepting layer may therefore remain absent of mobile charge carriers, ie mobile charge carriers may not flow from the charge reservoir layer into the second charge accepting layer in response to the application of the first applied input voltage. The second charge accepting layer may therefore remain unoccupied by mobile charge carrier in response to the application of the first applied input voltage. The second charge accepting layer may therefore continue to provide a high resistance to current flow in response to the application of the first applied input voltage. The second charge accepting layer may therefore remain non-conductive, ie insulating, in response to the application of the first applied input voltage.

In response to the application of the second applied input voltage, the lowest energy state of the charge reservoir layer may have a higher energy than the lowest energy state of the second charge accepting layer. In response to the application of the second applied input voltage, at least a portion of the lowest energy state of the second charge accepting layer may have a lower energy than the Fermi energy of the second charge accepting layer. Mobile charge carriers may therefore flow from the charge reservoir layer into the second charge accepting layer in response to the application of the second applied input voltage.

The second charge accepting layer may therefore become occupied in response to the application of the second applied input voltage. The second charge accepting layer may therefore provide a low resistance to current flow in response to the application of the second applied input voltage. The second charge accepting layer may therefore become conductive in response to the application of the second applied input voltage.

The number of mobile charge carriers in the charge reservoir layer may therefore be reduced in response to the application of the first applied input voltage. The charge reservoir layer may therefore become unoccupied by mobile charge carriers in response to the application of the second applied input voltage.

In response to the application of the second applied input voltage, the lowest energy state of the charge reservoir layer may have a lower energy than the lowest energy state of the first charge accepting layer. In response to the application of the second applied input voltage, the lowest energy state of the first charge accepting layer may have a higher energy than the Fermi energy of the first charge accepting layer.

The first charge accepting layer may therefore remain absent of mobile charge carriers, ie mobile charge carriers may not flow from the charge reservoir layer into the first charge accepting layer, in response to the application of the second applied input voltage. The first charge accepting layer may therefore remain unoccupied by mobile charge carriers in response to the application of the second applied input voltage. The first charge accepting layer may therefore continue to provide a high resistance to current flow in response to the application of the second applied input voltage. The first charge accepting layer may therefore remain non-conductive, ie insulating, in response to the application of the second applied input voltage.

The mobile charge carriers may be electrons or holes. Where the mobile charge carriers are electrons, the first applied input voltage may be a positive applied input voltage and the second applied input voltage may be a negative applied input voltage. Alternatively, the first applied input voltage may be a positive applied input voltage, and the second applied input voltage may be a less positive applied input voltage. This may be the case, for example, where a positive input voltage is applied in an at rest state, ie to create the potential well of the charge reservoir layer. Further alternatively, the second applied input voltage may be a negative applied input voltage, and the first applied input voltage may be a less negative applied input voltage. This may be the case, for example, where a negative input voltage is applied in an at rest state, ie to create the potential well of the charge reservoir layer.

Where the mobile charge carriers are holes, the first applied input voltage may be a negative applied input voltage and the second applied input voltage may be a positive applied input voltage. Alternatively, the first applied input voltage may be a negative applied input voltage, and the second applied bias may be a less negative applied input voltage. This may be the case, for example, where a negative input voltage is applied in an at rest state, ie to create the potential well of the charge reservoir layer. Further alternatively, the second applied input voltage may be a positive applied input voltage, and the first applied input voltage may be a less positive applied input voltage. This may be the case, for example, where a positive input voltage is applied in an at rest state, ie to create the potential well of the charge reservoir layer.

The semiconductor device may comprise planar layers. Any or all of the first charge accepting layer, the second charge accepting layer, the charge reservoir layer and the charge barrier layers may comprise a substantially planar layer. The semiconductor structure may therefore have a planar layered arrangement, ie the semiconductor layers and/or the charge barrier layers may be substantially planar. Alternatively, the semiconductor device may be arranged such that the semiconductor device layers and/or the charge barrier layers extend at least partially around one another, eg in the form of a nanowire. Each of the individual semiconductor device layers and/or the charge barrier layers may therefore be substantially cylindrical.

Where the abovementioned layers are substantially planar, the plane of each layer may be substantially parallel to the growth of the layers, and/or substantially parallel to the plane of the substrate. That is, the layers may be grown vertically on the substrate, ie in a direction perpendicular to the plane of the substrate, and/or in a direction parallel to the normal of the plane of the substrate. In contrast, the different terminal regions of a conventional CMOS gate (ie “p-n-p” or “n-p-n” doped regions) are arranged laterally on a substrate. Thus, the above features may be advantageous in that the vertical growth of the layers makes the gate more scalable. The absence of any lateral doping may also eliminate the issue of ‘short channel effects’.

The logic gate may be operated as an inverter. Thus, according to a further aspect of the invention, there is provided an inverter comprising a logic gate as described above.

The logic gate may form part of an array or sequence of logic gates configured to operate as a logic device or a digital circuit. For example, as described above, the logic gate according to the invention effectively acts as a conventional CMOS NOT gate. Correspondingly, since conventional CMOS logic always comprises pairs of nMOS and pMOS, ie equal numbers of nMOS and pMOS transistors one or more logic gate described above may be configured to form a logic device such as a NAND gate, a NOR gate, an OR gate, or an AND gate. Hence, according to a further aspect of the invention, there is provided a logic device or a digital circuit comprising one or more logic gates as described above. The logic device may be a NAND gate, a NOR gate, an OR gate, or an AND gate.

Practicable embodiments of the invention will now be described, by way of example only, with reference to the accompanying drawings, of which:

FIG. 1 is an electrical diagram of a conventional CMOS NOT logic gate known in the art;

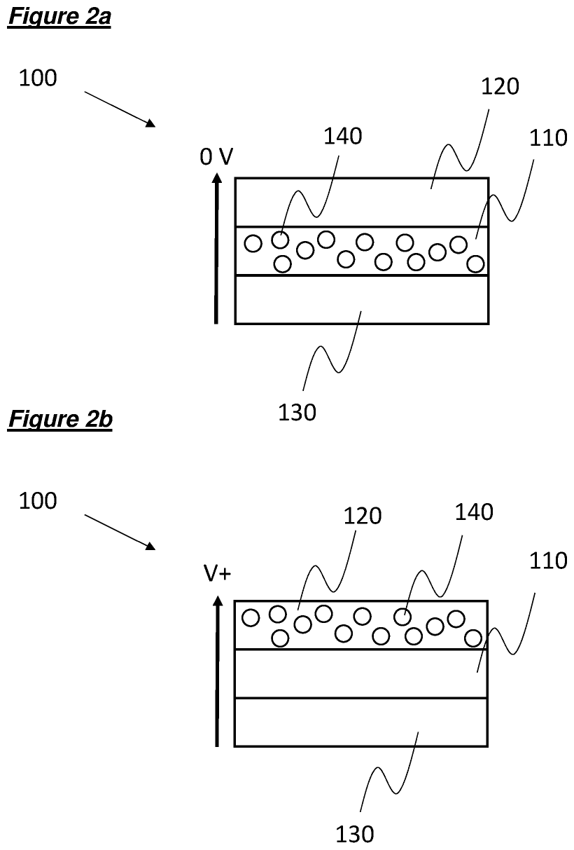

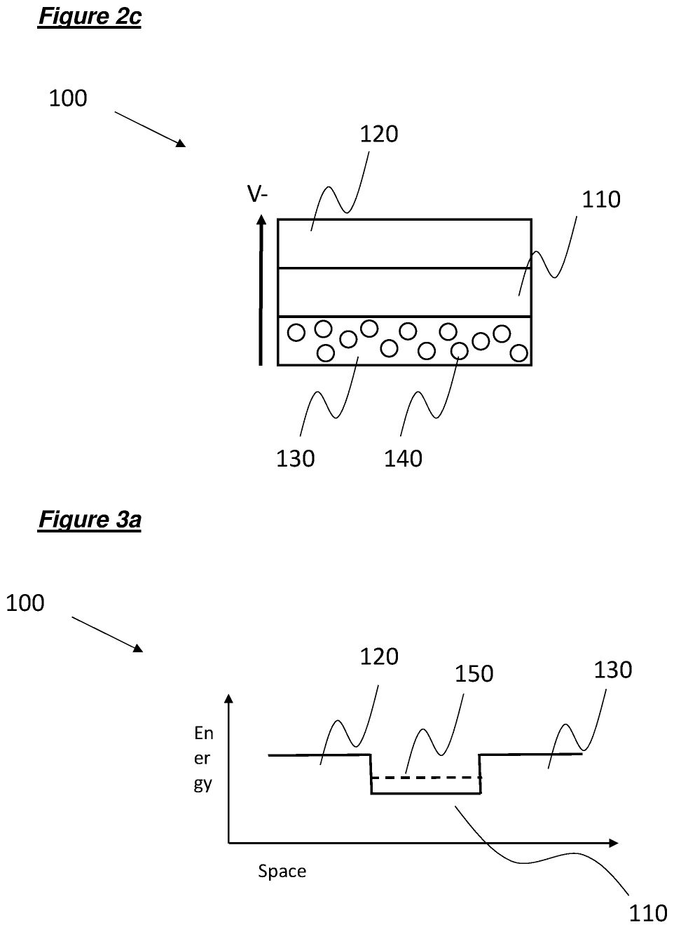

FIG. 2a is a cross-sectional view through a logic device according to an embodiment of the invention, in the absence of any bias applied across the device;

FIG. 2b is a cross-sectional view through the logic device of FIG. 2a, in the presence of a positive bias applied across the device;

FIG. 2c is a cross-sectional view through the logic device of FIG. 2a, in the presence of a negative bias applied across the device;

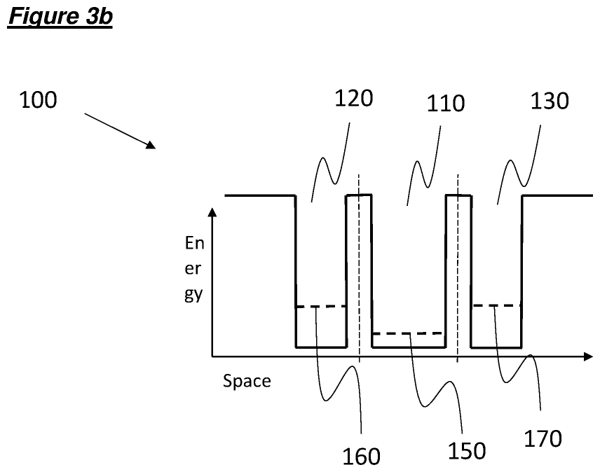

FIG. 3a is a schematic conduction band energy level diagram of a logic device according to a first embodiment of the invention;

FIG. 3b is a schematic conduction band energy level diagram of a logic device according to a second embodiment of the invention

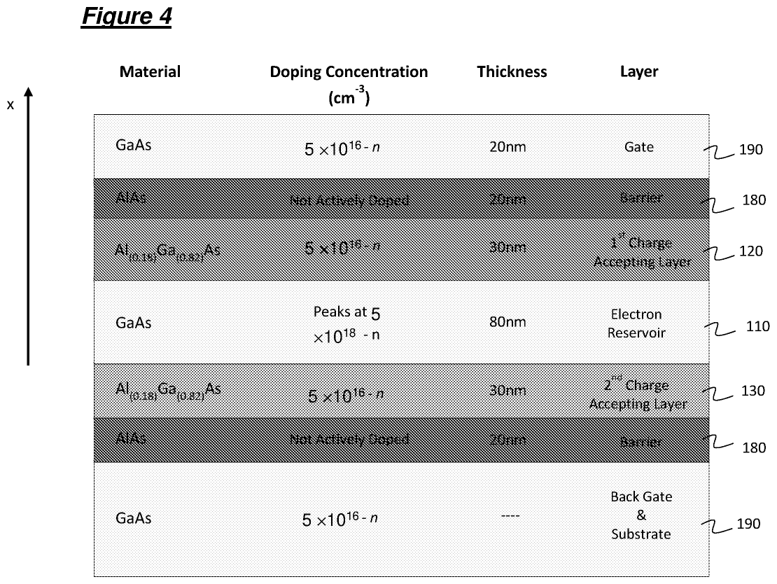

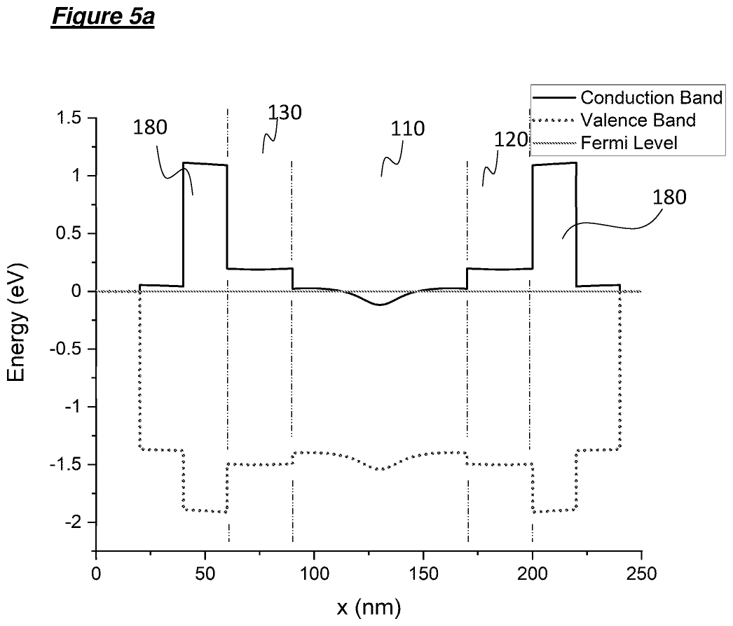

FIG. 4 is a is a cross-sectional view through a logic device according to an embodiment of the invention, indicating example materials used to form the logic device;

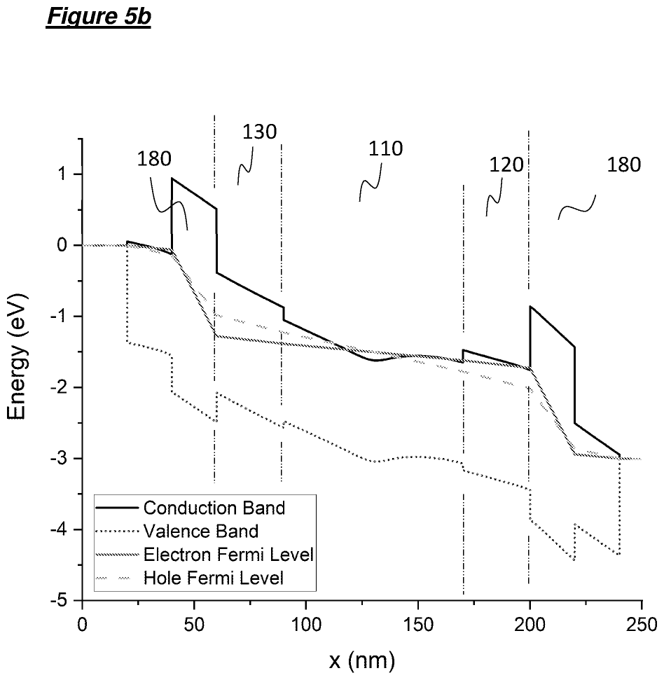

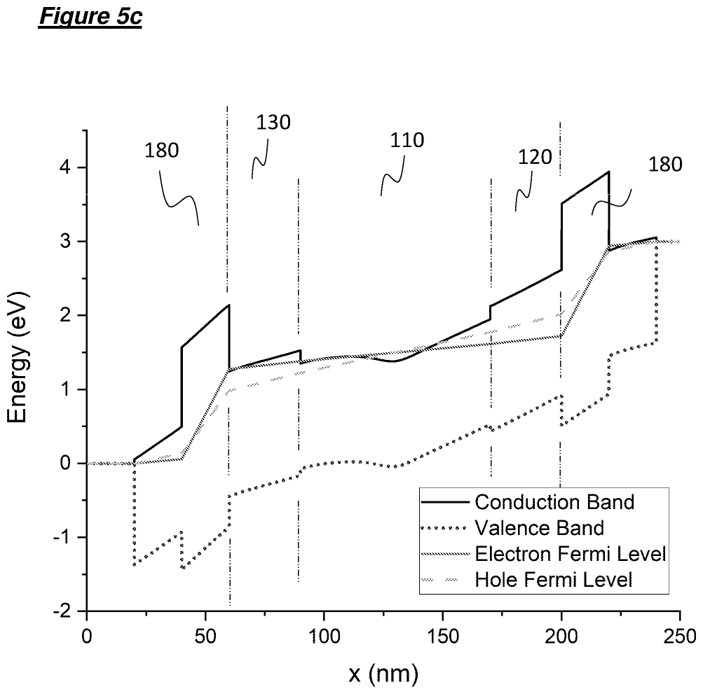

FIG. 5a is a simulated conduction band energy level diagram of the logic device of FIG. 4, in the absence of any bias applied across the device;

FIG. 5b is a simulated conduction band energy level diagram of the logic device of FIG. 4, in the presence of a positive bias applied across the device;

FIG. 5c is a simulated conduction band energy level diagram of the logic device of FIG. 4, in the presence of a negative bias applied across the device;

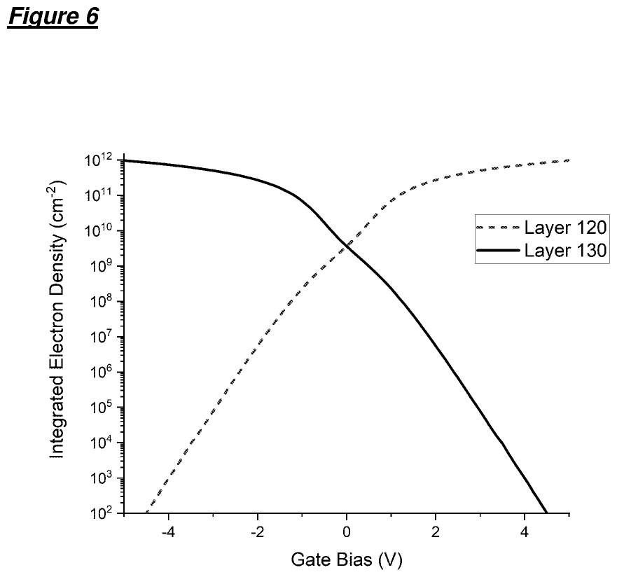

FIG. 6 is a graph plotting electron density against the bias applied across the device for the channel layers of the logic device of FIG. 4;

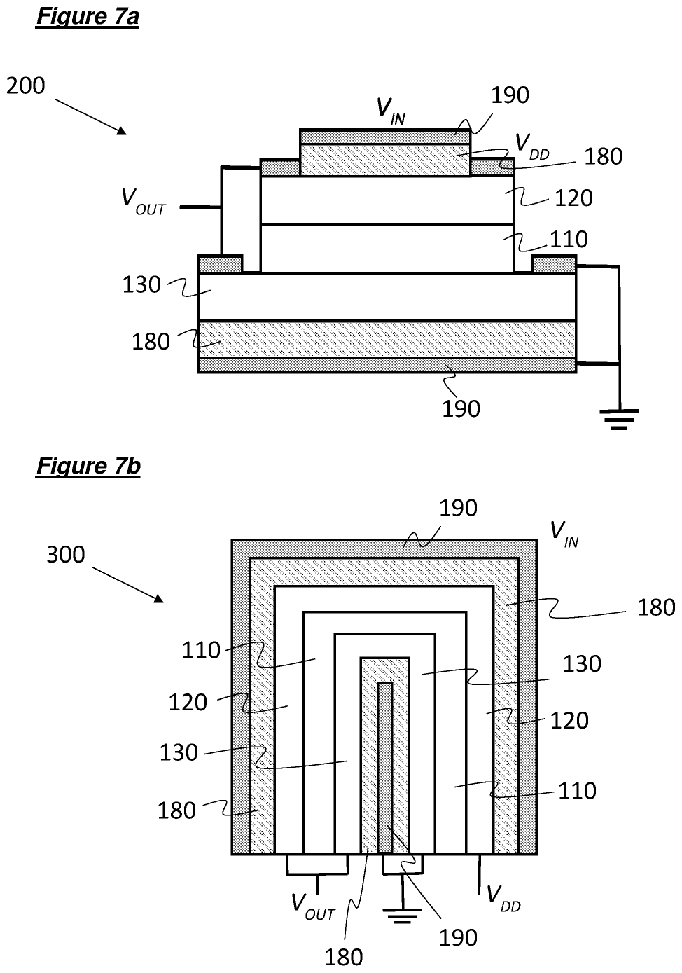

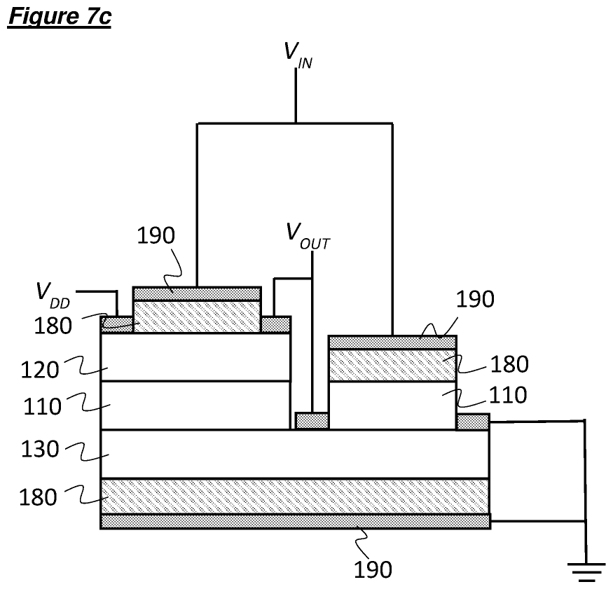

FIG. 7a is a cross-sectional view through an inverter 200 implementing a logic device according to a first embodiment of the invention;

FIG. 7b is a cross-sectional view through an inverter 300 implementing a logic device according to second and third embodiments of the invention;

FIG. 7c is a cross-sectional view through an inverter 300 implementing a logic device according to a fourth embodiment of the invention;

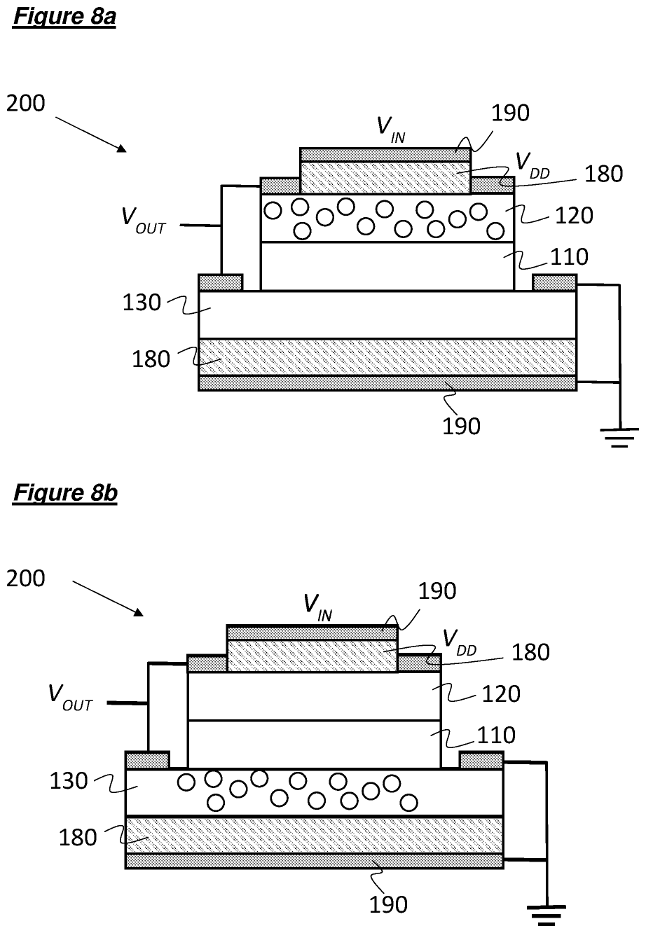

FIG. 8a is a cross-sectional view through the inverter 200 of FIG. 7a in the presence of a positive bias applied across the device;

FIG. 8b is a cross-sectional view through the inverter 200 of FIG. 7a in the presence of a negative bias applied across the device.

FIGS. 2a-2c illustrate the movement of charge carriers across a logic device 100 dependent on the application of a voltage bias to the logic device 100.

FIG. 2a illustrates a cross-sectional view through logic device 100. The logic device 100 comprises a charge reservoir 110, a first channel layer 120 (referred to as a “first charge accepting layer” in the invention defined above) and a second channel layer 130 (referred to as a “second charge accepting layer” in the invention defined above). In the absence of any applied bias, the charge carriers 140 of the logic device 100 reside in the charge reservoir 110. Where layers 120 and 130 are described as “channel” layers, it is meant that these layers are capable of accepting mobile charge carriers, thus making them capable of becoming conductive and acting as conventional channel layers in use.

FIG. 2b illustrates the same logic device 100 in the presence of an applied positive voltage bias. In response to the application of the positive bias, the charge carriers 140 of the logic device 100 move from the charge reservoir 110 into the first channel layer 120.

FIG. 2c illustrates the same logic device 100 in the presence of an applied negative bias. In response to the application of the negative bias, the charge carriers 140 of the logic device 100 move from the charge reservoir 110 into the second channel layer 130.

In the examples of FIGS. 2a-2c, the charge carriers 140 are electrons. However, it is anticipated that the charge carriers 140 could instead be holes, in which case the logic device would act in the opposite manner. That is, if the charge carriers 140 were holes, in response to the application of a positive bias, the charge carriers 140 of the logic device 100 would move from the charge reservoir 110 into the second channel layer 130, and in response to the application of a negative bias, the charge carriers 140 of the logic device 100 would move from the charge reservoir 110 into the first channel layer 120.

FIGS. 3a and 3b illustrate example conduction band minimum energy level diagrams for a logic device 100 that would achieve the behaviour described in relation to FIGS. 2a-2c.

FIG. 3a illustrates a first example of a logic device 100 in which the charge reservoir 110 is made of a first material having a relatively low conduction band edge energy, and the first and second channel layers 120, 130 are made of a different material having a relatively high conduction band edge energy level. By relatively low, it is meant that the conduction band edge energy of the charge reservoir 110 is lower than the conduction band edge energy of both of the first and second channel layers 120, 130. By relatively high, it is meant that the conduction band edge energy of both of the first and second channel layers 120, 130 is higher than the conduction band edge energy of the charge reservoir 110. As a result of the described difference in conduction band edge energies, the first and second channel 120, 130 define electrical potential barriers either side of the charge reservoir 110, such that a potential well is formed by the charge reservoir 110.

In the absence of an applied bias, the charge reservoir 110 therefore provides a lower energy state 150 for the charge carriers 140 to reside in than the first and second channel layers 120, 130 do, and the charge carriers 140 remain in the charge reservoir 110.

Upon the application of a positive bias, the conduction band edge is distorted one way, such that the first channel layer 120 provides a lower energy state for the charge carriers 140 to reside in than the charge reservoir 110 and the second channel layer 130 do, and as a result the charge carriers move from the charge reservoir 140 to the first channel layer 120.

Upon the application of a negative bias, the conduction band edge is distorted the opposite way, such that the second channel layer 130 provides a lower energy state for the charge carriers 140 to reside in than the charge reservoir 110 and the first channel layer 120 do, and as a result the charge carriers move from the charge reservoir 140 to the second channel layer 130.

FIG. 3b illustrates a second example in which a quantum well is formed in each of the charge reservoir 110, the first channel layer 120 and the second channel layer 130 by the presence of charge barriers, but the quantum well of the charge reservoir 110 is much wider than the quantum wells of the first channel layer 120 and the second channel layer 130.

In the absence of an applied bias, the charge reservoir 110 therefore provides an energy state 150 that is lower than the energy states 160, 170 provided by the first and second channel layers 120, 130, and the charge carriers 140 remain in the charge reservoir 110.

Upon the application of a positive bias, the conduction band edge is distorted one way, such that the lowest energy state 160 of the first channel layer 120 becomes lower than the energy states 150, 170 of the charge reservoir 110 and the second channel layer 130 respectively, and as a result the charge carriers move from the charge reservoir 140 to the first channel layer 120.

Upon the application of a negative bias, the conduction band edge is distorted the opposite way, such that the lowest energy state 170 of the second channel layer 130 becomes lower than the energy states 150, 160 of the charge reservoir 110 and the first channel layer 120 respectively, and as a result the charge carriers move from the charge reservoir 140 to the second channel layer 130.

This provision of energy states and band edge distortion is described in more detail in relation to FIGS. 5a-5c, in which the conduction and valence band edge energies across the logic device 100 have been simulated at 300K in a one-dimensional model (vertically through the device) using a Schrödinger-Poisson solver in the effective mass approximation.

In the energy diagrams of FIGS. 5a-5c, the logic device 100 is formed according to the layered arrangement illustrated in FIG. 4. In FIG. 4, the charge reservoir 110 is formed of a 80 nm thick layer of gallium arsenide (GaAs), and the first and second channel layers 120, 130 are formed of 30 nm thick layers of aluminium gallium arsenide (Al_{0.18}Ga_{0.82}As) either side of the charge reservoir 110.

This arrangement is chosen because GaAs/AlGaAs is the most mature and well-understood compound semiconductor system, and because varying the Al fraction in the AlGaAs layer changes the bandgap and the conduction and valence band edges with respect to the GaAs layer, whilst causing only a minimal change in the lattice constant. This enables a multi-layered GaAs/AlₓGa₁₋ₓAs heterostructure material to be grown whilst engineering the conduction and valence band edges as required, with high quality and little or no strain. However, it is anticipated that other semiconductor materials, including other III-V semiconductor materials, may be used.

Positioned on the outer sides of the channel layers 120, 130 are insulating layers 180, which are both formed of a 20 nm thick layer of aluminium arsenide (AlAs). Finally, placed on the outer sides of the insulating layers 180 are gates 190, through which a bias may be applied across the device 100 in use. The entire device 100 may also be built upon a substrate.

In FIGS. 5a-5c, the x-axis represents the thickness of the logic device 100 (ie vertically from top to bottom along the x axis through the device 100 as illustrated in FIG. 4), and the y-axis represents the energy of the band edges.

FIG. 5a illustrates the simulated schematic band energy diagram of the proposed logic device 100 in the absence of any applied bias. From FIG. 5a it can be seen that for charge reservoir 110 (at least at the edges) and the channel layers 120, 130, the Fermi level lies within the band gap (ie between the conduction and valence band edges), meaning the electrons 140 remain in the central portion of the charge reservoir 110 such that there is an absence of mobile electrons in the channel layers 120 and 130, as previously described. Thus, no current is able to flow in the channel layers 120 and 130 of the logic device 100, and the device 100 is in an “off” state.

FIG. 5b illustrates the simulated schematic band energy diagram of the proposed logic device 100 in the presence of a +3V bias. As a result of the applied bias, the conduction and valence band edges are distorted vertically, such that the electron Fermi level is above the conduction band edge minimum in the first channel layer 120. Although this is not immediately obvious in FIG. 5b, upon closer inspection it can be seen that the electron Fermi level is above the conduction band edge minimum at the outer periphery of the first channel layer 120. Thus, electrons 140 of the logic device 100 move from the charge reservoir 110 into the first channel layer 120, making the first channel layer 120 highly conductive.

In contrast, the Fermi level remains within the band gap in both the charge reservoir 110 (at least at the edges) and the second channel layer 130, meaning no current is able to flow into the second channel layer 130. Also of importance is that hole Fermi level remains within the band gap across the charge reservoir 110 and the channel layers 120, 130, preventing any hole transport during operation.

FIG. 5c illustrates the simulated schematic band energy diagram of the proposed logic device 100 in the presence of a −3V bias. As a result of the applied bias, the conduction and valence band edges are distorted vertically, such that the electron Fermi level is above the conduction band edge minimum in the second channel layer 130. Although this is not immediately obvious in FIG. 5c, upon closer inspection it can be seen that the electron Fermi level is above the conduction band edge minimum at the outer periphery of the second channel layer 130. Thus, electrons 140 of the logic device 100 move from the charge reservoir 110 into the first channel layer 130, making the first channel layer 130 highly conductive.

In contrast, the Fermi level remains within the band gap in both the charge reservoir 110 (at least at the edges) and the first channel layer 120, meaning no current is able to flow into the second channel layer 120. Of importance is that hole Fermi level remains within the band gap across the charge reservoir 110 and the channel layers 120, 130, preventing any hole transport during operation.

It should also be noted that due to the vertical symmetry of the layers (ignoring any substrate upon which the device 100 is grown), the application of an equal and opposite bias to the top gate 190 will have an equal and opposite effect on the operation of the device 100.

FIG. 6 illustrates this transfer of electrons dependent on the bias applied across the device 100. In FIG. 6, the x-axis represents the bias applied across the device, and the y-axis represents the integrated electron density in each of the first and second channel layers 120, 130 as a result of the bias applied across the device 100.

Where a negative bias is applied, the second channel layer 130 has a high integrated electron density, such that it is highly conductive, and the first channel layer 120 has a very low integrated electron density, such that it is non-conductive. Where a positive bias is applied, the second channel layer 130 has a very low integrated electron density, such that it is non-conductive, and the first channel layer 120 has a high integrated electron density, such that it is highly conductive. Although a small electron density is present in the first channel layer 120 in the presence of zero applied bias and in the presence of a negative applied bias, and a small electron density is present in the second channel layer 130 in the presence of zero applied bias and in the presence of a positive applied bias, this is as a result of the simulation conditions. In a real device with a finite size that is typical of modern electronic devices, the number of mobile electrons in those channels under such conditions will be less than one, and thus have no effect on the operation of the device.

FIG. 7a illustrates a first embodiment in which the logic device 100 described herein can be used as part of an inverter 200. The inverter 200 of FIG. 7a comprises a planar layered arrangement in which a charge reservoir 110 is sandwiched between first and second channel layers 120, 130, and this arrangement is itself sandwiched between insulating layers 180. Gates 190 are applied either side of the insulating layers 190, and an inlet voltage V_{IN} is provided to the upper gate 190. Lower gate 190 is connected to ground. Source and drain terminals are also provided to both the first channel layer 120 and the second channel layer 130. A drive voltage V_{DD} is provided to the first channel layer 120 via the drain terminal, and the drain terminal of the second channel layer 130 is connected to ground. An outlet voltage V_{OUT} is provided via source terminals of the first and second channel layers 120, 130.

FIG. 7b illustrates a cross-section through two further possible embodiments, in which the logic device 100 described herein can be used as part of an inverter 300, the inverter being provided in the form of a ‘FINFET’ device and a nanowire respectively. Since both forms would have the same cross-section, both embodiments are described in relation to FIG. 7b.

In the second embodiment, the inverter 300 of FIG. 7b operates in the same way as the inverter 200 of FIG. 7a, but is provided in the form of a ‘FinFET’ device, in which the plane of the layers runs into the page. ‘FinFET’ devices may be considered advantageous over conventional planar devices as gates, and thus gate voltage, may be applied to three sides of the device, rather than one. In this regard, the inverter 300 comprises a layered arrangement in which an inner gate 190 is surrounded by insulating layer 180, which in turn is surrounded by a second channel layer 130, which in turn is surrounded by charge reservoir 110, which in turn is surrounded by a first channel layer 120, which in turn is surrounded by insulating layer 180, and the entire arrangement is surrounded by an outer gate 190. Source and drain terminals are provided to first and second channel layers 120, 130 as in the embodiment of FIG. 7a, and the terminals are connected to ground and provide an inlet voltage V_{IN}, a drive voltage V_{DD} and an outlet voltage V_{OUT} in the same way as the embodiment of FIG. 7a too.

In the third embodiment, the inverter 300 of FIG. 7b is provided in the form of a nanowire. In a similar manner to the ‘FinFET’, such a nanowire device may be considered advantageous over conventional planar devices as gates, and thus electric fields, may be applied around the device. In this regard, the inverter 300 comprises a cylindrically layered arrangement in which an inner gate 190 is surrounded by insulating layer 180, which in turn is surrounded by a second channel layer 130, which in turn is surrounded by charge reservoir 110, which in turn is surrounded by a first channel layer 120, which in turn is surrounded by insulating layer 180, and the entire arrangement is surrounded by an outer gate 190. Source and drain terminals are provided to first and second channel layers 120, 130 as in the embodiment of FIG. 7a, and the terminals are connected to ground and provide an inlet voltage V_{IN}, a drive voltage V_{DD} and an outlet voltage V_{OUT} in the same way as the embodiment of FIG. 7a too.

FIG. 7c illustrates a fourth embodiment of the logic device 100 described herein which can be used as part of an inverter 300. The inverter 300 of FIG. 7c operates in the same way as the inverter 200 of FIG. 7a, but is provided with an alternative geometry for an upper gate 190, in which two separate upper gates 190 are provided. This enables the voltage V_{IN} to be simultaneously applied to the first charge accepting layer 120 (via the left-hand side arrangement in FIG. 7c) and the charge reservoir layer 110 (via the right-hand side arrangement of FIG. 7c). This may be advantageous for the operation of the logic device 100, particularly where the logic device 100 forms part of a larger logic device or digital circuit.

FIGS. 8a and 8b illustrate the inverter 200 of FIG. 7a in use. In FIG. 8a, where a positive voltage is applied across the device 200 via the top gate 190 (V_{IN}), the electrons move from the charge reservoir 110 into the first channel layer 120 as described above in relation to the relative band edge energy diagrams. This creates a low resistance state between the source and drain terminals of the first channel layer 120, and a relatively high resistance state between the source and drain terminals of the second channel layer 130. This enables current to flow across the first channel layer 120 with low resistance, such that any voltage applied to the device 200 at V_{DD} is output via V_{OUT}.

In contrast, in FIG. 8b, where a negative voltage is applied across the device 200 via the top gate 190 (V_{IN}), the electrons move from the charge reservoir 110 into the second channel layer 130 as described above in relation to the relative band edge energy diagrams. This creates a low resistance state between the source and drain terminals of the second channel layer 130, and a relatively high resistance state between the source and drain terminals of the first channel layer 120. This prevents any current flowing across the first channel layer 120 and allows current to flow across the second channel layer 130 with low resistance, such that the voltage output at V_{OUT} is ground.

In this regard, the inverter device 200 functions similar to a conventional CMOS logic device, ie where first channel layer 120 acts as the pMOS layer, and second channel layer 130 acts as the nMOS layer. Similar to conventional CMOS logic devices, the devices according to the invention may be combined to form other digital logic gates, such as AND, NAND, OR, or NOR logic gates.

It is also anticipated that instead of using metallic gates 190 in the arrangement of FIGS. 7a, 7b, 8a and 8b, a highly doped semiconductor could be used, which would effectively act in the same way as a metallic gate.

1. A logic gate comprising a semiconductor device, the semiconductor device including a charge reservoir layer disposed between a first charge accepting layer and a second charge accepting layer, the first charge accepting layer defining a first current flow path that is connected to a common output contact at one end and a first drive contact at the other end, and the second charge accepting layer defining a current flow path that is connected to the common output contact at one end and a second drive contact at the other end, the charge reservoir layer comprising a potential well having a lowest energy state for mobile charge carriers that is at a lower energy than the lowest energy state for mobile charge carriers of both the first and second charge accepting layers, the logic gate further comprising a control gate and a ground electrode that are separated from the charge accepting layers by non-conducting layers, the control gate and the ground electrode configured to apply an input voltage across the semiconductor device, such that mobile charge carriers confined within the charge reservoir layer are transferred to the first charge accepting layer at a first applied input voltage and transferred to the second charge accepting layer at a second applied input voltage.

2. A logic gate according to claim 1, wherein the first charge accepting layer and/or the second charge accepting layer are non-conductive in the absence of an applied input voltage.

3. A logic gate according to claim 2, wherein the first charge accepting layer remains non-conductive in response to the application of the second applied input voltage.

4. A logic gate according to claim 2, wherein the second charge accepting layer remains non-conductive in response to the application of the first applied input voltage.

5. A logic gate according to claim 1, wherein the mobile charge carriers are electrons.

6. A logic gate according to claim 5, wherein the first applied input voltage is a positive applied input voltage, and the second applied bias is a negative applied input voltage.

7.-8. (canceled)

9. A logic gate according to claim 1, wherein the semiconductor device comprises a heterostructure.

10. A logic gate according to claim 1, wherein the charge reservoir layer comprises a quantum well defined between the first charge accepting layer and the second semiconductor layer.

11. (canceled)

12. A logic gate according to claim 1, wherein the lowest energy state for mobile charge carriers in a conduction band of the first charge accepting layer and a conduction band of the second charge accepting layer has a higher energy than the lowest energy state of the charge reservoir layer.

13. A logic gate according to claim 1, wherein in response to the application of the first applied input voltage, the lowest energy state of at least a portion of the charge reservoir layer has a higher energy than at least a portion of the conduction band energy of the first charge accepting layer.

14. (canceled)

15. A logic gate according to claim 1, wherein in response to the application of the first applied input voltage, the lowest energy state of the charge reservoir layer has a lower energy than the conduction band energy of the second charge accepting layer.

16. (canceled)

17. A logic gate according to claim 1, wherein in response to the application of the second applied input voltage, the lowest energy state of at least a portion of the charge reservoir layer has a higher energy than at least a portion of the conduction band energy of the second charge accepting layer.

18. (canceled)

19. A logic gate according to claim 1, wherein in response to the application of the second applied input voltage, the lowest energy state of the charge reservoir layer has a lower energy than the conduction band energy of the first charge accepting layer.

20. (canceled)

21. A logic gate according to claim 1, wherein the first charge accepting layer comprises a potential well defined between a first external charge barrier and a first internal charge barrier, and the second charge accepting layer comprises a potential well defined between a second external charge barrier and a second internal charge barrier.

22. A logic gate according to claim 21, wherein the potential well of the first semiconductor layer, and/or the potential well of the second semiconductor layer, are quantum wells having discrete internal energy levels for accommodating charge carriers in those layers, wherein the lowest energy state of the first charge accepting layer, and the lowest energy state of the second charge accepting layer, have a higher energy than the lowest energy state of the charge reservoir layer.

23. (canceled)

24. A logic gate according to claim 22, wherein in response to the application of the first applied input voltage, the lowest energy state of the charge reservoir layer has a higher energy than the lowest energy state of the first charge accepting layer.

25. (canceled)

26. A logic gate according to claim 22, wherein in response to the application of the first applied input voltage, the lowest energy state of the charge reservoir layer has a lower energy than the lowest energy state of the second charge accepting layer.

27. (canceled)

28. A logic gate according to claim 22, wherein in response to the application of the second applied input voltage, the lowest energy state of the charge reservoir layer has a higher energy than the lowest energy state of the second charge accepting layer.

29. (canceled)

30. A logic gate according to claim 22, wherein in response to the application of the second applied input voltage, the lowest energy state of the charge reservoir layer has a lower energy than the lowest energy state of the first charge accepting layer.

31. (canceled)

32. A logic device or a digital circuit comprising one or more logic gate according to claim 1.
